(19) United States
(12) Patent Application Publication
(10) Pub. No.: US 2023/0268392 A1
(43) Pub. Date: Aug. 24, 2023

(54) SHARED CONTACT DEVICES WITH CONTACTS EXTENDING INTO A CHANNEL LAYER

(71) Applicant: Intel Corporation, Santa Clara, CA (US)

(72) Inventors: Abhishek A. Sharma, Hillsboro, OR (US); Wilfred Gomes, Portland, OR (US); Sagar Suthram, Portland, OR (US); Tahir Ghani, Portland, OR (US); Anand S. Murthy, Portland, OR (US)

(73) Assignee: Intel Corporation, Santa Clara, CA (US)

(21) Appl. No.: 17/678,928

(22) Filed: Feb. 23, 2022

(51) Int. Cl. H01L 29/06; H01L 29/423; H01L 29/786; H01L 29/66; H01L 27/088

(52) U.S. Cl. CPC H01L 29/0669; H01L 29/42392; H01L 29/78696; H01L 29/78618; H01L 29/66742; H01L 27/0886

(57) ABSTRACT

The scaling of features in ICs has been a driving force behind an ever-growing semiconductor industry. As transistors of the ICs become smaller, their gate lengths become smaller, leading to undesirable short-channel effects such as poor leakage, poor subthreshold swing, drain-induced barrier lowering, etc. Embodiments of the present disclosure are based on recognition that extending at least one of two S/D contacts of a transistor into a channel layer while keeping it separated from a corresponding gate stack by a channel material may allow keeping the footprint of the transistor relatively small while effectively increasing transistor's effective gate length and thus reducing the negative impacts of short-channel effects. This architecture may be optimized even further if transistors are to be operated at relatively low temperatures, e.g., below 200 Kelvin degrees or lower. For multiple transistors, some of the S/D contacts may be shared to further increase transistor density.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of transistors, e.g., field-effect transistors (FETs), that share their source and/or drain contacts may help with such an optimization.

Since, as is common in the field of FETs, designations of “source” and “drain” are often interchangeable, source and drain contacts of a transistor may be referred to as first and second source or drain (S/D) contacts, where, in some embodiments, the first S/D contact is a source contact and the second S/D contact is a drain contact and, in other embodiments, this designation of source and drain contacts is reversed.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C are cross-sectional side views of an IC device with a non-shared S/D contact extending into a channel layer and a shared S/D contact not extending into a channel layer, in accordance with various embodiments.

FIGS. 2A-2C are cross-sectional side views of an IC device with a non-shared S/D contact extending into a channel layer and a shared S/D contact extending through a channel layer and being in contact with a gate stack of at least one of the transistors, in accordance with various embodiments.

FIGS. 3A-3C are cross-sectional side views of an IC device with a non-shared S/D contact extending into a channel layer and a shared S/D contact extending through a channel layer and being separated from a gate stack of at least one of the transistors by a channel material, in accordance with various embodiments.

FIG. 4 is a cross-sectional side view of an IC device with a non-shared S/D contact extending into a channel layer and a gate stack of at least one of the transistors being only partially recessed into a channel layer, in accordance with some embodiments.

FIG. 5 is a cross-sectional side view of an IC device with a non-shared S/D contact extending into a channel layer and a gate stack of at least one of the transistors not being recessed into a channel layer, in accordance with some embodiments.

FIG. 6 is a cross-sectional side view of an IC device with a non-shared S/D contact extending into a channel layer and being in contact with a corresponding gate stack, in accordance with some embodiments.

FIG. 7 is a cross-sectional side view of an IC device with non-shared S/D contacts being at the bottom and a shared S/D contact being at the top of a channel layer, in accordance with some embodiments.

FIGS. 8A-8D are cross-sectional side views of a S/D contact that could be implemented at the top of a channel layer, in accordance with various embodiments.

FIGS. 9A-9D are cross-sectional side views of a S/D contact that could be implemented at the bottom of a channel layer, in accordance with various embodiments.

FIG. 10 is a high-level cross-sectional side view of an IC device assembly with transistor layers configured for operation at different temperatures, in accordance with some embodiments.

FIG. 11 is a flow diagram of an example method of manufacturing a shared contact IC device with one or more S/D contacts extending into a channel layer, in accordance with some embodiments.

FIG. 12 provides top views of a wafer and dies that include one or more shared contact IC devices with S/D contacts extending into a channel layer in accordance with any of the embodiments disclosed herein.

FIG. 13 is a cross-sectional side view of an IC package that may include one or more shared contact IC devices with S/D contacts extending into a channel layer in accordance with any of the embodiments disclosed herein.

FIG. 14 is a cross-sectional side view of an IC device assembly that may include one or more shared contact IC devices with S/D contacts extending into a channel layer in accordance with any of the embodiments disclosed herein.

FIG. 15 is a block diagram of an example computing device that includes one or more shared contact IC devices with S/D contacts extending into a channel layer in accordance with any of the embodiments disclosed herein.

FIG. 16 is a block diagram of an example processing device that includes one or more shared contact IC devices with S/D contacts extending into a channel layer in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating shared contact IC devices with S/D contacts extending into a channel layer and associated arrangements as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

As described above, the scaling of features in ICs has been a driving force behind an ever-growing semiconductor industry. As transistors of the ICs become smaller (i.e., as their footprints are reduced), their gate lengths become smaller. However, reducing gate lengths of transistors leads to undesirable short-channel effects such as poor leakage, poor subthreshold swing, drain-induced barrier lowering, etc. Embodiments of the present disclosure are based on recognition that extending at least one of two S/D contacts of a transistor into a channel layer while keeping it separated from a corresponding gate stack by a channel material may allow keeping the footprint of the transistor relatively small and comparable to what could be achieved implementing a transistor with a shorter gate length while effectively increasing transistor's effective gate length and thus reducing the negative impacts of short-channel effects. Extending a S/D contact into a channel layer may further improve contact resistance as it increases a surface of an interface between the S/D contact and the channel layer. Embodiments of the present disclosure are further based on recognition that this architecture may be optimized even further if transistors are to be operated at relatively low temperatures, where, as used herein, low-temperature operation (or “lower-temperature” operation) refers to operation at temperatures below room temperature, e.g., below 200 Kelvin degrees or lower. Thermal energy is much lower at low temperatures and, consequently, the off-current (|off) of a transistor is much lower and the subthreshold swing is much sharper, compared to room temperature operation. Consequently, if a transistor is operated at low temperatures, its gate length can be shorter than what can be achieved at room temperatures, while keeping the short-channel effects at a level that does not significantly compromise transistor performance. As a result, at low temperatures, it may even be feasible to extend at least one of the S/D contacts of a transistor into a channel layer without keeping it separated from a corresponding gate stack by a channel material, or to decrease the footprint of the transistor, further decreasing its gate length. Across multiple transistors implemented based on a common channel layer, some of the S/D contacts may be shared, which may further allow increasing density of transistors in a given footprint area (the footprint area being defined as an area in a plane of the support structure, or a plane parallel to the plane of the support structure), or, conversely, allow reducing the footprint area of an IC with a given transistor density.

In various implementations of shared contact IC devices with S/D contacts extending into a channel layer, the channel layer may be of any suitable geometry, enabling forming transistors of planar architectures or non-planar architectures. Transistors of planar architectures may include silicon-on-insulator (SOI) transistors, single-gate transistors, double-gate transistors, thin-film transistors (TFTs), and so on. Transistors of non-planar architectures may include fin-based FETs (FinFETs), nanoribbon transistors, nanowire transistors, and so on.

In the following detailed description, various aspects of the illustrative implementations may be described using terms commonly employed by those skilled in the art to convey the substance of their work to others skilled in the art. For example, the terms “channel layer” and “channel material” may be used interchangeably. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, analogous elements designated in the present drawings with different reference numerals after a dash, e.g., transistors 110-1, 110-2, and so on may be referred to together without the reference numerals after the dash, e.g., as “transistors 110.” In order to not clutter the drawings, if multiple instances of certain elements are illustrated, only some of the elements may be labeled with a reference sign.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of shared contact IC devices with S/D contacts extending into a channel layer as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various shared contact IC devices with S/D contacts extending into a channel layer as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

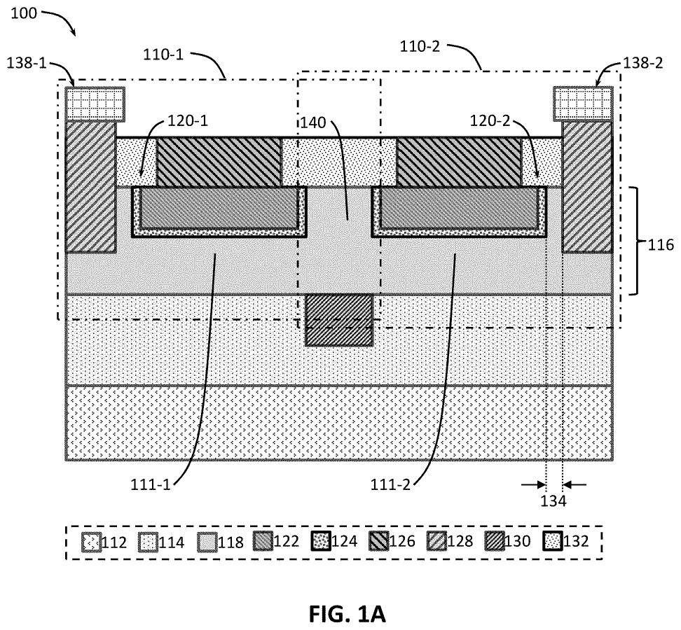

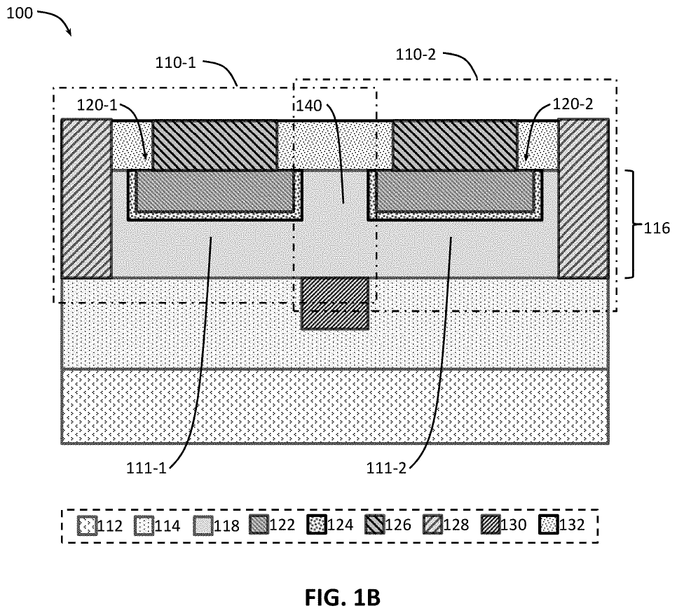

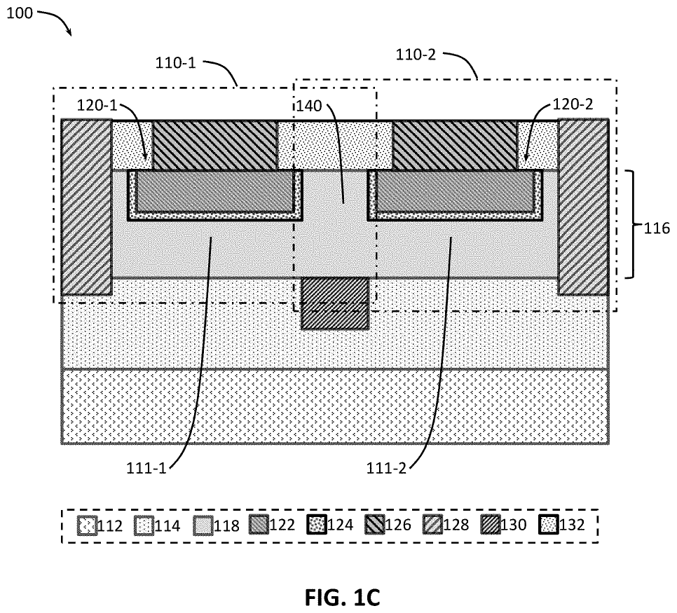

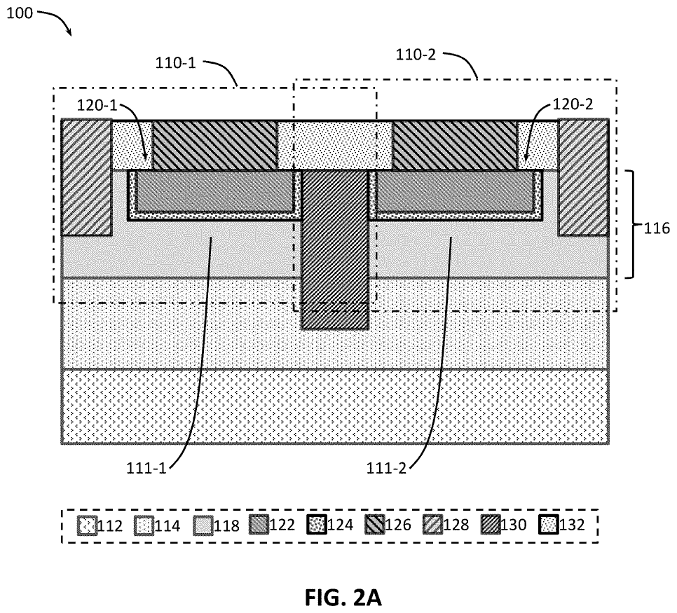

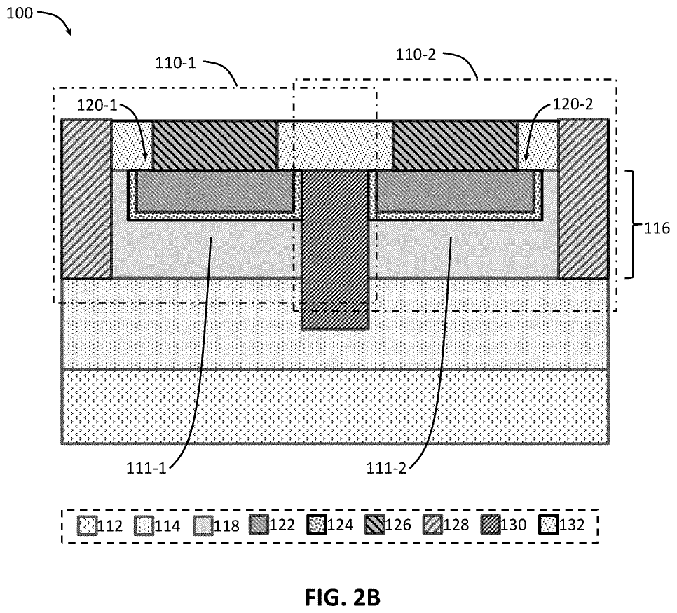

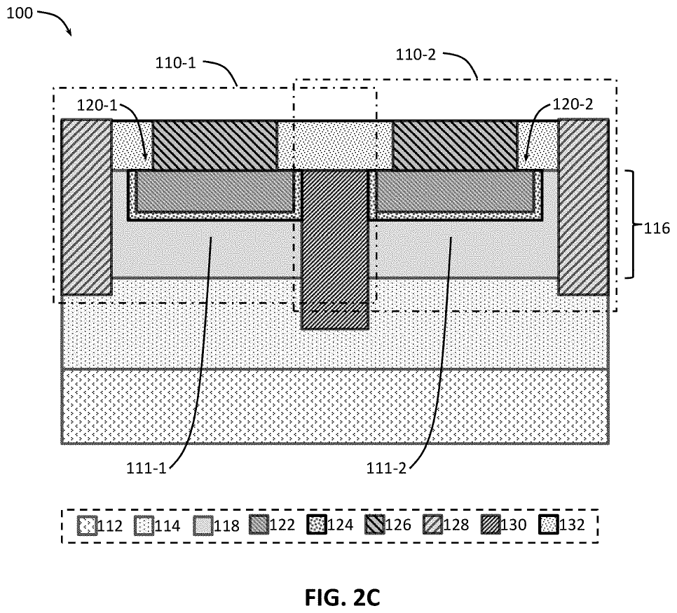

FIGS. 1A-1C are cross-sectional side views of an IC device 100 with a non-shared S/D contact extending into a channel layer and a shared S/D contact not extending into a channel layer, in accordance with various embodiments. A number of elements labeled in FIGS. 1A-1C, as well in some of the subsequent drawings (e.g., FIGS. 2-7) with reference numerals are indicated in these drawings with different patterns in order to not clutter the drawings with too many reference numerals, with a legend showing the correspondence between the reference numerals and patterns being provided at the bottom of the drawings. For example, the legend illustrates that FIGS. 1A-1C use different patterns to show a support structure 112, an intermediate layer 114, a channel material 118, etc.

The IC device 100 may include a plurality of transistors 110 provided over a support structure 112. The transistors 110 are shown in FIG. 1A as a transistor 110-1 and a transistor 110-2, the approximate outline of each transistor 110 illustrated in FIG. 1A with a dash-dotted contour. In some embodiments, an intermediate layer 114 may be provided over the support structure 112, and then a layer 116 of a channel material 118 that will serve as a basis for channel regions 111 of the transistor 110 may be provided over the intermediate layer 114 (hence, the layer 116 may be referred to as a “channel layer 116”). The channel layer 116 may be shaped to enable the transistors 110 to be of any suitable architecture. For example, the channel layer 116 may be shaped as a fin, a nanoribbon, or a nanowire to enable non-planar transistor architectures, or be a planar layer to enable planar transistor architectures.

In general, implementations of the present disclosure may be formed or carried out on a substrate, such as a semiconductor substrate composed of semiconductor material systems including, for example, N-type or P-type materials systems. In one implementation, the semiconductor substrate may be a crystalline substrate formed using a bulk silicon or a SOI substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the substrate may be a printed circuit board (PCB) substrate. The support structure 112 may be any such substrate. Although a few examples of materials from which the substrate may be formed are described here, any material that may serve as a foundation upon which the transistors 110 with shared contacts as described herein may be built falls within the spirit and scope of the present disclosure.

The intermediate layer 114 may be a frontend layer, e.g., a layer with a plurality of frontend devices, e.g., frontend transistors, such as FinFETs, nanosheet transistors, nanoribbon transistors, nanowire transistors, or planar transistors. In some embodiments, the intermediate layer 114 may also include one or more backend layers, e.g., one or more backend memory layers. Details of the intermediate layer 114 are not shown because various manners for arranging various devices and interconnects are known in the art, all of which being within the scope of the present disclosure. The intermediate layer 114 may include an insulator material that surrounds and electrically isolates various devices from one another. In some embodiments, the insulator material of the intermediate layer 114 may include any suitable interlayer dielectric (ILD) material such as silicon oxide, carbon-doped silicon oxide, silicon carbide, silicon nitride, aluminum oxide, and/or silicon oxynitride. In various embodiments, such an insulator material may include a low-k dielectric material. Examples of the low-k dielectric materials that may be used as the insulator material in the IC device 100 include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the insulator material in the IC device 100 include organic polymers such as polyimide, polynorbornenes, benzocyclobutene, perfluorocyclobutane, or polytetrafluoroethylene (PTFE). Still other examples of low-k dielectric materials that may be used as the insulator material in the IC device 100 include silicon-based polymeric dielectrics such as hydrogen silsesquioxane (HSQ) and methylsilsesquioxane (MSQ). Other examples of low-k materials that may be used in the insulator material in the IC device 100 include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1. In some embodiments, the intermediate layer 114 may not include any active devices such as transistors; in such embodiments, the intermediate layer 114 may still include an insulator material as described above, in which some of the S/D contacts of the transistors 110 may be provided.

In general, the channel material 118 may be composed of semiconductor material systems including, for example, N-type or P-type materials systems. In some embodiments, the channel material 118 may include a substantially monocrystalline semiconductor, such as silicon (Si) or germanium (Ge). In some embodiments, the channel material 118 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 118 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 118 may include a combination of semiconductor materials.

For some example N-type transistor embodiments (i.e., for the embodiments where the transistor 110 is an N-type metal-oxide-semiconductor (NMOS) transistor), the channel material 118 may include a III-V material having a relatively high electron mobility, such as, but not limited to InGaAs, InP, InSb, and InAs. For some such embodiments, the channel material 118 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material 118 may advantageously be a group IV material having a high hole mobility, such as, but not limited to Ge or a Ge-rich SiGe alloy. For some example embodiments, the channel material 118 may have a Ge content between 0.6 and 0.9, and advantageously may be at least 0.7.

In some embodiments, the channel material 118 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 118 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material 118 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, the transistors 110 may be TFTs. A TFT is a special kind of a FET made by depositing a thin film of an active semiconductor material over a support (e.g., the support structure 112) that may be a non-conducting support. Some such materials may be deposited at relatively low temperatures, which allows depositing them within the thermal budgets imposed on back end fabrication to avoid damaging the front end components such as the logic devices of an IC device 100. At least a portion of the active semiconductor material forms a channel of the TFT. In some such embodiments, the channel material 118 may be deposited as a thin film and may include any of the oxide semiconductor materials described above.

In other embodiments, instead of being deposited at relatively low temperatures as described above with reference to the TFTs, the channel material 118 may be epitaxially grown in what typically involves relatively high-temperature processing. In such embodiments, the channel material 118 may include any of the semiconductor materials described above, including oxide semiconductor materials. In some such embodiments, the channel material 118 may be epitaxially grown directly on a semiconductor layer of a support structure over which the transistor 110 will be fabricated, in a process known as “monolithic integration.” In other such embodiments, the channel material 118 may be epitaxially grown on a semiconductor layer of another support structure and then the epitaxially grown layer of the channel material 118 may be transferred, in a process known as a “layer transfer,” to a support structure of which the transistor 110 will be fabricated, in which case the latter support structure may but does not have to include a semiconductor layer prior to the layer transfer. Layer transfer advantageously allows forming non-planar transistors, such as FinFETs or all-around gate transistors such as nanowire or nanoribbon transistors, over support structures or in layers that do not include semiconductor materials (e.g., in the back end of an IC device). Layer transfer also advantageously allows forming transistors of any architecture (e.g., non-planar or planar transistors) without imposing the negative effects of the relatively high-temperature epitaxial growth process on devices that may already be present over a support structure.

The channel material 118 deposited at relatively low temperatures is typically a polycrystalline, polymorphous, or amorphous semiconductor, or any combination thereof. The channel material 118 epitaxially grown is typically a highly crystalline (e.g., monocrystalline or single-crystalline) material. Therefore, whether the channel material 118 is deposited at relatively low temperatures or epitaxially grown can be identified by inspecting grain size of the active portions of the channel material 118 (e.g., of the portions of the channel material 118 that form channels of transistors). An average grain size of the channel material 118 being between about 0.5 and 1 millimeters (in which case the material may be polycrystalline) or smaller than about 0.5 millimeter (in which case the material may be polymorphous or amorphous) may be indicative of the channel material 118 having been deposited (e.g., in which case the transistors in which such channel material 118 is included are TFTs). On the other hand, an average grain size of the channel material 118 being equal to or greater than about 1 millimeter (in which case the material may be a single-crystal material) may be indicative of the channel material 118 having been epitaxially grown and included in the final device either by monolithic integration or by layer transfer.

In still other embodiments, the channel material 118 may include one or more of so-called “two-dimensional (2D)” semiconductor materials such as graphene, molybdenum disulfide (MoS₂), tungsten disulfide (WS₂), black phosphorous, or other thin-film semiconductor materials. Such embodiments may be advantageous because bandgaps of 2D semiconductor materials may be modified relatively easy.

In some embodiments, the channel layer 116 may have a thickness (i.e., a dimension measured in a direction that is substantially perpendicular to the support structure 112) between about 5 and 75 nanometers, including all values and ranges therein, e.g., between about 5 and 50 nanometers or between about 5 and 30 nanometers. Even though the IC device 100 is illustrated in the present drawings as having the channel material 118 that is common between the first and second transistors 110, in some embodiments, material composition of the channel material 118 of the channel region 111-1 may be different from material composition of the channel material 118 of the channel region 111-2 (e.g., the transistor 110-1 may be an NMOS while the transistor 110-2 may be a PMOS, or vice versa).

As shown in FIG. 1A, each of the transistors 110 may include a gate stack 120 that may include a gate electrode material 122 and, optionally, a gate insulator material 124. The transistors 110 shown in FIG. 1A are top-gated transistors, since their respective channel regions 111 in the channel material 118 are between the support structure 112 and the respective gate stacks 120, although this may be different in other embodiments. Furthermore, the gate stacks 120 shown in FIG. 1A are entirely recessed into the channel material 118, so that the tops of the gate stacks 120 may be aligned with the top of the channel material 118, as illustrated in FIG. 1A. Recessing the gate stacks 120 of the transistors 110 into the channel material 118 may have the advantage of an increased gate length for the same surface area occupied by a gate stack.

As shown in FIG. 1A, the gate insulator material 124 may be provided so that at least a portion of the gate insulator material 124 is between the gate electrode material 122 and a portion of the channel material 118 that forms a channel region of a respective transistor 110. The gate electrode material 122 may include at least one P-type work function metal or N-type work function metal, depending on whether the transistor 110 is a PMOS transistor or an NMOS transistor (P-type work function metal used as the gate electrode material 122 when the transistor 110 is a PMOS transistor and N-type work function metal used as the gate electrode material 122 when the transistor 110 is an NMOS transistor). For a PMOS transistor, metals that may be used for the gate electrode material 122 may include, but are not limited to, ruthenium, palladium, platinum, cobalt, nickel, and conductive metal oxides (e.g., ruthenium oxide). For an NMOS transistor, metals that may be used for the gate electrode material 122 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 122 may include a stack of two or more metal layers, where one or more metal layers are work function metal layers and at least one metal layer is a fill metal layer. Further layers may be included next to the gate electrode material 122 for other purposes, such as to act as a diffusion barrier layer or/and an adhesion layer.

In some embodiments, the gate insulator material 124 may include one or more high-k dielectrics and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate insulator material 124 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator material 124 during manufacture of the IC device 100 to improve the quality of the gate insulator material 124. The gate insulator material 124 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 120 may be surrounded by a gate spacer 132. The gate spacer 132 could be configured to provide separation between the gate stack 120 and source/drain contacts 128 of the transistors 110 and could be made of a low-k dielectric material, some examples of which have been provided above with respect to the insulator material of the intermediate layer 114. The gate spacer 132 may include pores or air gaps to further reduce its dielectric constant.

In some embodiments, the gate insulator material 124 may include a hysteretic material or a hysteretic arrangement, which, together, may be referred to as a “hysteretic element.” Transistors 110 in which the gate insulator 124 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a voltage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high speed writing. In addition, hysteretic memories may be manufactured using processes compatible with the standard complementary metal-oxide-semiconductor (CMOS) technology. Therefore, over the last few years, these types of memories have emerged as promising candidates for many growing applications.

In some embodiments, the hysteretic element of the gate insulator material 124 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator material 124 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

FIG. 1A further illustrates that each of the transistors 110 includes a gate contact 126, coupled to (e.g., in conductive contact with) the gate electrode material 122 of the respective transistor 110, as well as a pair of S/D contacts that includes a first S/D contact 128 and a second S/D contact 130. As shown in FIG. 1A, each of the transistors 110-1, 110-2 includes its own, respective, first S/D contact 128, while the second S/D contact 130 is shared between the transistors 110-1 and 110-2. FIG. 1A further illustrates a shared S/D region 140 between the transistors 110-1 and 110-2.

In some embodiments, the shared S/D region 140 may include a doped semiconductor material. In general, the shared S/D region 140 may be formed using either an implantation/diffusion process or an etching/deposition process. In the former process, dopants such as boron, aluminum, antimony, phosphorous, or arsenic may be ion-implanted into the channel material 118 to form the shared S/D region 140. An annealing process that activates the dopants and causes them to diffuse further into the channel material 118 may follow the ion implantation process. In the latter process, a portion of the channel material 118 may first be etched to form a recess at the location of the future shared S/D region 140. An epitaxial deposition process may then be carried out to fill the recess with material that is used to fabricate the S shared S/D region 140. In some implementations, the shared S/D region 140 may be fabricated using a silicon alloy such as silicon germanium or silicon carbide. In some implementations the epitaxially deposited silicon alloy may be doped in situ with dopants such as boron, arsenic, or phosphorous. In further embodiments, the shared S/D region 140 may be formed using one or more alternate semiconductor materials such as germanium or a group III-V material or alloy. And in further embodiments, one or more layers of metal and/or metal alloys may be used to form the shared S/D region 140. In other embodiments, the shared S/D region 140 may include a semiconductor material that is not deliberately doped.

Each of the gate contact 126, the S/D contacts 128, and the second S/D contact 130, as well as various interconnects that may be included in the IC device 100 may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In the IC device 100 shown in FIG. 1A, the first S/D contacts 128 contact the front (i.e., top) side of the channel material 118 (i.e., the first S/D contacts 128 contact the surface of the channel material 118 that is the farthest away from the support structure 112), while the second S/D contact 130 contacts the back (i.e., bottom) side of the channel material 118 (i.e., the second S/D contact 130 contacts the surface of the channel material 118 that is closer to the support structure 112 than the front side). Thus, the first S/D contacts 128 are front-side contacts, while the second S/D contact 130 is a back-side contact. Having different S/D contacts being on different sides of the channel material 118 may be advantageous in terms of simplifying routing of connections to these contacts. For example, typically, space above the transistors of an IC device is crowded with various other components and interconnects, so moving the second S/D contact 130 to the back side of the channel material 118 makes the space less crowded and/or allows space to be used for other purposes. Having different S/D contacts being on different sides of the channel material 118 may also be advantageous in terms of increasing the effective gate length of the transistors 110.

Furthermore, in the IC device 100 shown in FIG. 1A, the first S/D contacts 128 partially extend into the channel material 118 (i.e., the first S/D contacts 128 are closer to the support structure 112 than the front side of the channel material 118, but they do not reach the back side of the channel material 118), while the second S/D contact 130 does not extend into the channel material 118 (i.e., the second S/D contact 130 is aligned with the back side of the channel material 118). Having the first S/D contacts 128 extend into the channel material 118 advantageously allows increasing contact interface between the first S/D contacts 128 and the channel material 118, thereby decreasing contact resistance, which leads to improved transistor performance. This is different from conventional transistors where S/D contacts are provided over the front or back side of the channel material but do not extend into the channel material.

Another feature unique in the IC device 100 shown in FIG. 1A compared to conventional transistors is that the first S/D contacts 128 are not in contact with their respective gate stacks 120 but are separated from the gate stacks 120 by the channel material 118. In some embodiments, a distance 134 between a given first S/D contact 128 and a respective gate stack 120 (labeled in FIG. 1A for the transistor 110-2, but the same applies to the transistor 110-1) may be between about 1 and 20 nanometers, including all values and ranges therein, e.g., between about 1 and 10 nanometers, or between about 1 and 5 nanometers. Having the S/D contact that extends into the channel material 118 be at a distance from the gate stack 120 that also extends into the channel material 118 advantageously increases the effective gate length of the transistor without increasing its footprint.

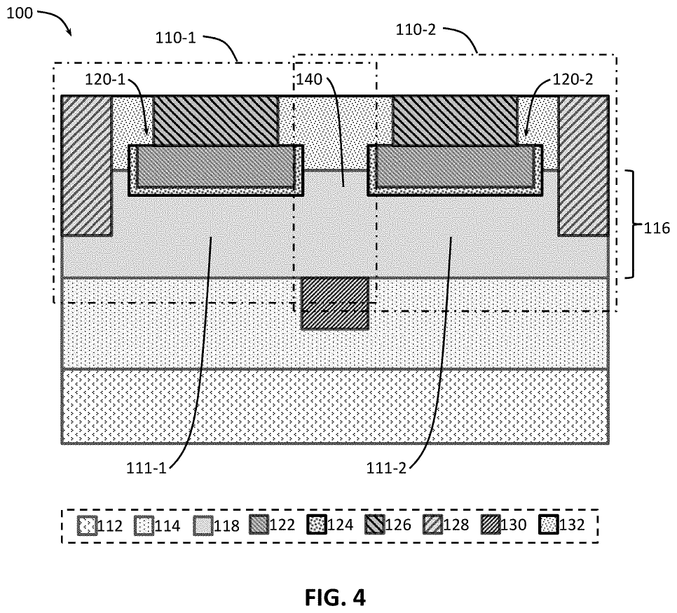

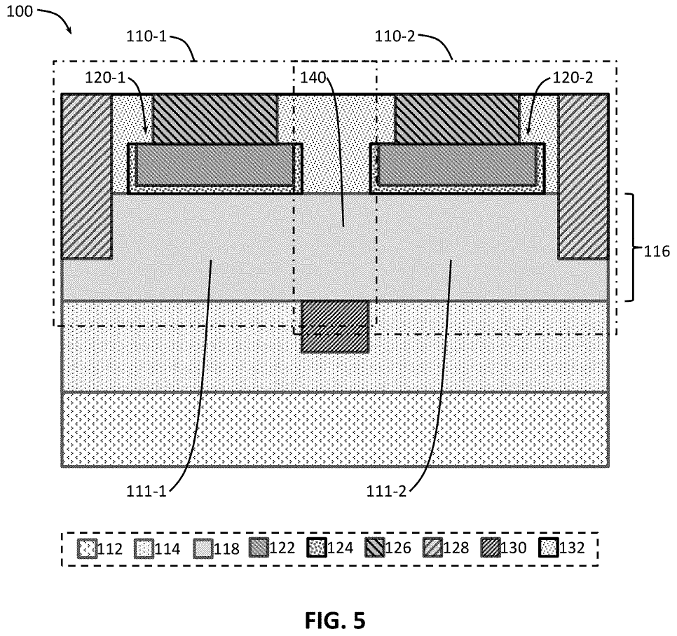

Although FIG. 1A illustrates that both gate stacks 120 are recessed into the channel material 118, in other embodiments, only one of them may be recessed and the other one may be not recessed (e.g., as shown in FIG. 5), or at least partially recessed (e.g., as shown in FIG. 4). Furthermore, although FIG. 1A illustrates both first S/D contacts 128 being at a distance from their respective gate stacks 120, in other embodiments, only one of them may be at a distance from its respective gate stack 120 and the other one may be in contact with its respective gate stack 120.

In some embodiments, a transistor with one or more S/D contacts extending into a channel layer may be coupled to a storage element, thus forming a 1T-1X memory cell of a memory array, where “1T” in the term “1T-1X memory cell” indicates that the memory cell includes one transistor (T), and where “1X” in the term “1T-1X memory cell” indicates that the memory cell includes one storage element (X). In other embodiments, a transistor with one or more S/D contacts extending into a channel layer may be coupled to multiple storage elements, or a transistor with one or more S/D contacts extending into a channel layer may be coupled to another transistor, to form one or more memory cells of a memory array, all of which being within the scope of the present disclosure.

One example of 1T-1X memory is illustrated in FIG. 1A, showing that the first S/D contact 128 of the transistor 110-1 may be coupled to a storage element 138-1, while the first S/D contact 128 of the transistor 110-2 may be coupled to a storage element 138-2. As an example, a dynamic random-access memory (DRAM) cell may include a storage element 138 in a form of a capacitor for storing a bit value, or a memory state (e.g., logical “1” or “0”) of the cell, and an access transistor, implemented as one of the transistors 110, controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). In other embodiments, any one of the storage elements 138 may be any other kind of components capable of storing a memory state, such as a magnetoresistive element, ferroelectric element, or a resistance-changing element. The storage elements 138-1 and 138-2 are not shown in subsequent drawings illustrating other embodiments of the IC device 100 in order to not clutter these drawings, but they may be present in any of these embodiments in the same manner as shown in FIG. 1A.

FIG. 1A illustrates an embodiment where the first S/D contacts 128 extend only partially into the channel material 118. FIG. 1B illustrates another embodiment of the IC device 100, which is substantially the same as that shown in FIG. 1A, except that the first S/D contacts 128 extend through all of the channel material 118 and are aligned with the back side of the channel material 118. FIG. 1C illustrates yet another embodiment of the IC device 100, which is substantially the same as that shown in FIG. 1A, except that the first S/D contacts 128 extend through all of the channel material 118 and further into the intermediate layer 114 (i.e., the first S/D contacts 128 extend past the back side of the channel material 118).

FIGS. 1A-1C illustrate embodiments where the non-shared S/D contacts (i.e., first S/D contacts 128) extend into the channel layer 116 and the shared S/D contact (i.e., the second S/D contact 130) does not extend into the channel layer 116. FIGS. 2A-2C illustrate embodiments where both the non-shared S/D contacts and the shared S/D contact extend into the channel layer 116. In particular, FIG. 2A illustrates another embodiment of the IC device 100, which is substantially the same as that shown in FIG. 1A, except that the second S/D contact 130 extends into and through the channel material 118, where it may be aligned with the front side of the channel material 118. Having the second S/D contact 130 extend through the channel material 118 may provide the advantage of a clear separation between the channel region 111-1 of the first transistor 110-1 and the channel region 111-2 of the second transistor 110-2. In further embodiments of the IC device 100 with back-side second S/D contact 130, the second S/D contact 130 may extend only partially into the channel material 118, i.e., it may extend above the back side of the channel material 118 but not reach the front side of the channel material 118 as shown in FIGS. 2A-2C.

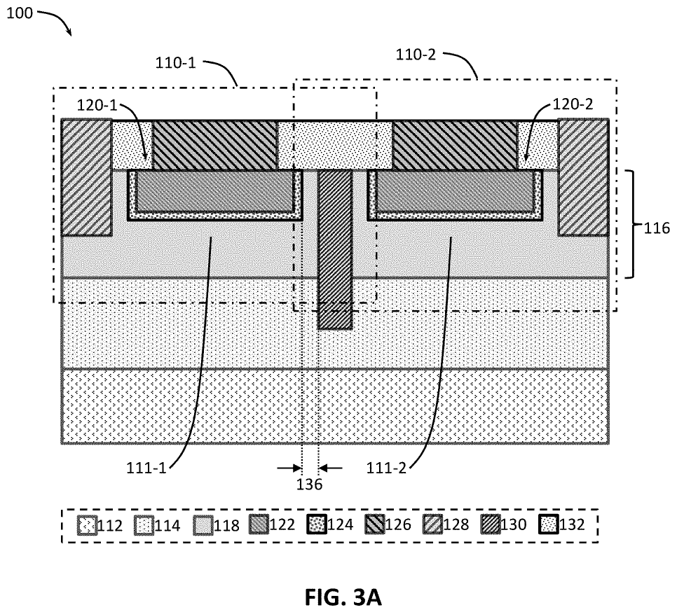

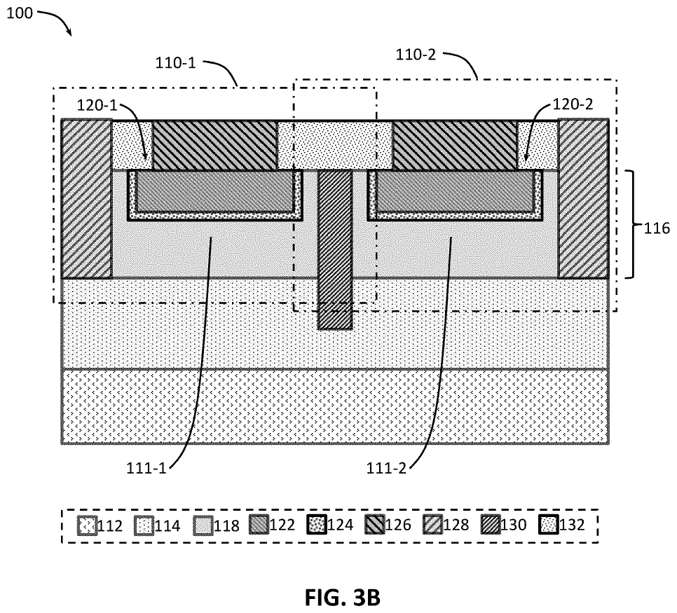

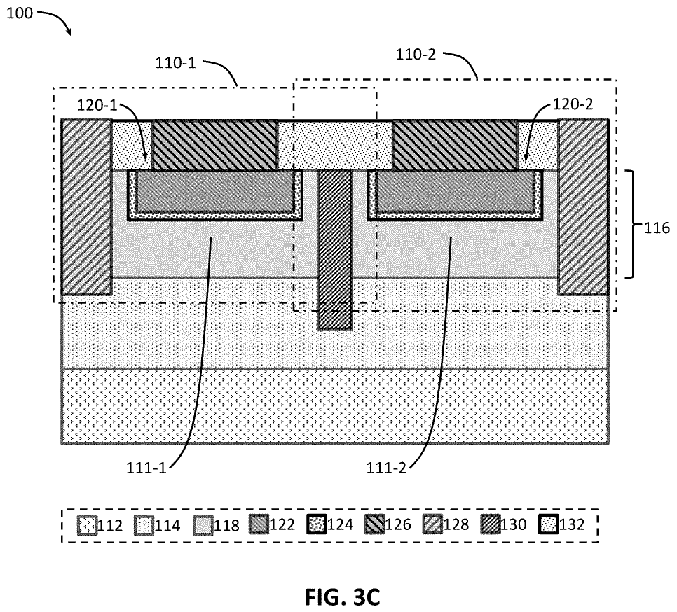

FIGS. 2A-2C illustrate embodiments where the shared S/D contact 130 that extends into the channel layer 116 is in contact with the gate stacks 120 on either side of the contact. FIGS. 3A-3C illustrate embodiments where both the non-shared S/D contacts and the shared S/D contact extend into the channel layer 116, but where the shared S/D contact (i.e., the second S/D contact 130) is separated from a gate stack 120 of at least one of the transistors 110 by the channel material 118. In particular, FIG. 3A illustrates another embodiment of the IC device 100, which is substantially the same as that shown in FIG. 2A, except that the second S/D contact 130 is separated from the gate stacks 120 by the channel material 118. In some embodiments, a distance 136 between the second S/D contact 130 and a respective gate stack 120 (labeled in FIG. 2A for the transistor 110-1, but the same applies to the transistor 110-2) may be between about 1 and 20 nanometers, including all values and ranges therein, e.g., between about 1 and 10 nanometers, or between about 1 and 5 nanometers. Having the second S/D contact 130 that extends into the channel material 118 be at a distance from the gate stack 120 that also extends into the channel material 118 advantageously allows increasing contact interface between the second S/D contact 130 and the channel material 118, thereby decreasing contact resistance, which leads to improved transistor performance. Although FIG. 3A illustrates the second S/D contact 130 being at a distance from both of the gate stacks 120, in other embodiments, only one of the gate stacks 120 may be at a distance from the second S/D contact 130 and the other one may be in contact with the second S/D contact 130.

FIG. 3B illustrates another embodiment of the IC device 100, which is substantially the same as that shown in FIG. 1B, except that the second S/D contact 130 extends into the channel material 118 as described with reference to FIG. 2 and is separated from the gate stacks 120 by the channel material 118 as described with reference to FIG. 3A. Similarly, FIG. 3C illustrates another embodiment of the IC device 100, which is substantially the same as that shown in FIG. 1C, except that the second S/D contact 130 extends into the channel material 118 as described with reference to FIG. 2 and is separated from the gate stacks 120 by the channel material 118 as described with reference to FIG. 3A.

FIGS. 1-3 illustrate embodiments of the IC device 100 where the gate stacks 120 are entirely recessed into the channel material 118. FIG. 4 shows that, in some embodiments of the IC device 100, one or both of the gate stacks 120 may be only partially recessed. In such embodiments, portions of the gate stacks 120 may be extending into the channel material 118, while other portions of the gate stacks 120 may be in the gate spacer 132. On the other hand, when the gate stacks 120 are entirely recessed into the channel material 118, as shown in FIGS. 1-3, the gates do not have any portions in the gate spacer 132. While FIG. 4 illustrates an embodiment that is substantially the same as shown in FIG. 1A, but with the gate stacks 120 being only partially recessed into the channel material 118, the feature of one or both of the gate stacks 120 being only partially recessed may be combined with any other embodiments of the IC device 100, described herein, e.g., with embodiments of any of FIGS. 1B-1C, FIGS. 2A-2C, or FIGS. 3A-3C.

Still further, in some embodiments of the IC device 100, one or both of the gate stacks 120 may be not recessed into the channel material 118 at all, as is shown in FIG. 5. In such embodiments, no portions of the gate stacks 120 may be extending into the channel material 118, and the gate stacks 120 may be in the gate spacer 132. While FIG. 5 illustrates an embodiment that is substantially the same as shown in FIG. 1A, but with the gate stacks 120 not being recessed into the channel material 118, the feature of one or both of the gate stacks 120 not being recessed may be combined with any other embodiments of the IC device 100, described herein, e.g., with embodiments of any of FIGS. 1B-1C, FIGS. 2A-2C, or FIGS. 3A-3C.

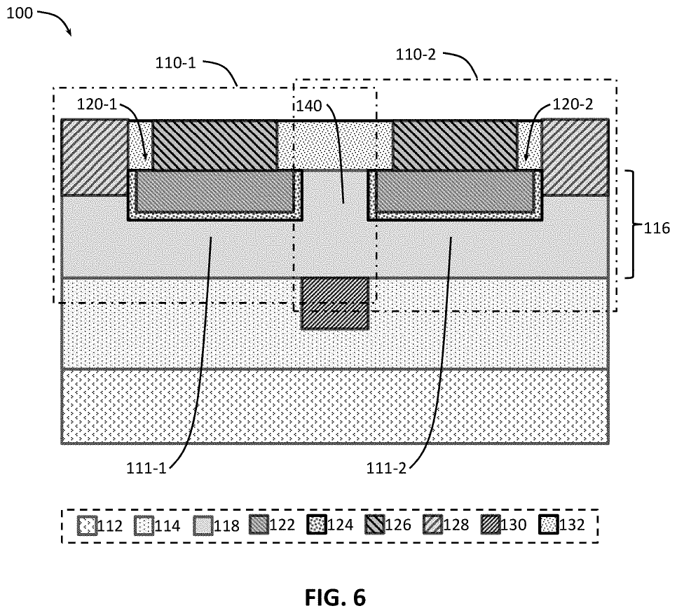

FIGS. 1-4 illustrate embodiments of the IC device 100 where the first S/D contacts 128 are separated from the at least partially recessed gate stacks 120 by the channel material 118. FIG. 6 shows that, in some embodiments of the IC device 100, one or both of the gate stacks 120 that are at least partially recessed into the channel material 118 may be in contact with the respective first S/D contact 128. While FIG. 6 illustrates an embodiment that is substantially the same as shown in FIG. 1A, but with the gate stacks 120 being in contact with the respective first S/D contact 128, the feature of one or both of the gate stacks 120 being in contact with the respective first S/D contact 128 may be combined with any other embodiments of the IC device 100 where the gate stacks 120 are at least partially recessed, described herein, e.g., with embodiments of any of FIGS. 1B-1C, FIGS. 2A-2C, FIGS. 3A-3C, or FIG. 4. Although FIG. 5 illustrates both first S/D contacts 128 being in contact with their respective gate stacks 120, in other embodiments, only one of them may be in contact with its respective gate stack 120 and the other one may be at a distance from its respective gate stack 120.

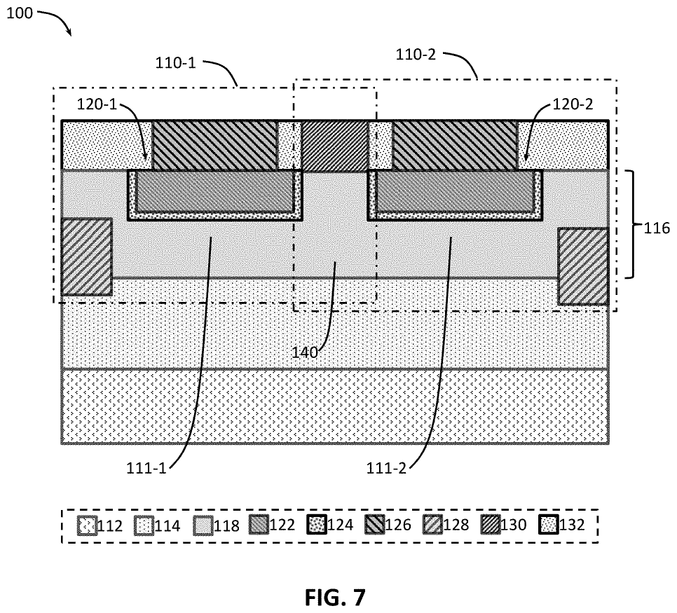

FIGS. 1-6 illustrate embodiments of the IC device 100 where the first S/D contacts 128 are front-side contacts and the second S/D contact 130 is a back-side contact. FIG. 7 shows that, in some embodiments of the IC device 100, the first S/D contacts 128 are back-side contacts and the second S/D contact 130 is a front-side contact. While FIG. 7 illustrates an embodiment that is substantially the same as shown in FIG. 1A, but with the first S/D contacts 128 being back-side contacts and the second S/D contact 130 being a front-side contact, the feature of the first S/D contacts 128 being back-side contacts and the second S/D contact 130 being a front-side contact may be combined with any other embodiments of the IC device 100, described herein, e.g., with embodiments of any of FIGS. 1B-1C, FIGS. 2A-2C, FIGS. 3A-3C, or FIGS. 4-6.

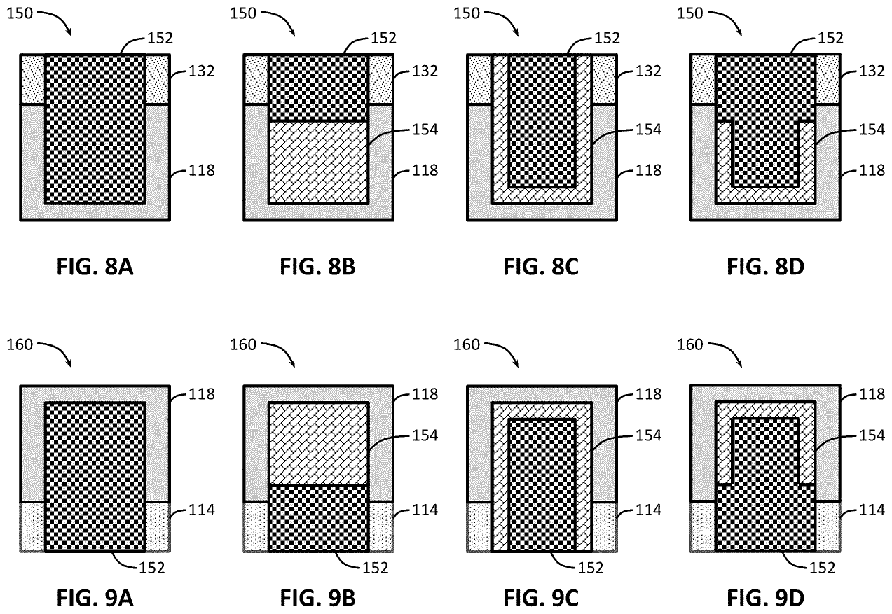

FIGS. 8A-8D are cross-sectional side views of a S/D contact 150 that could be implemented at the top of a channel layer (e.g., the channel layer 116), in accordance with various embodiments. Thus, the S/D contact 150 is a front-side contact of the IC device 100 and may be either one of the first S/D contacts 128 for any embodiments of FIGS. 1-6 or the second S/D contact 130 for the embodiment of FIG. 7. Since the S/D contact 150 may be implemented in any embodiments of the IC device 100 as shown in FIGS. 1-7, or in any combination of these embodiments, FIGS. 8A-8D illustrate the channel material 118 and the gate spacer 132 surrounding, respectively, bottom and top portions of the S/D contact 150, but further details of the IC device 100 are not shown in order to not clutter the drawings of FIGS. 8A-8D. In some embodiments of the IC device 100, what is illustrated as the gate spacer 132 in FIGS. 8A-8D and in other drawings of the present disclosure may be any suitable insulator material, not necessarily the same material as that used on sidewalls of the gates as a gate spacer.

FIG. 8A illustrates an embodiment where the S/D contact 150 may include only a contact metal 152. The contact metal 152 may include any metal, a metal alloy, or a stack of multiple metals, with metals such as copper, ruthenium, palladium, platinum, cobalt, nickel, hafnium, zirconium, titanium, tantalum, and aluminum. In some embodiments, contact metal 152 may include one or more electrically conductive alloys oxides or carbides of one or more metals.

FIG. 8B illustrates an embodiment where the S/D contact 150 may include not only a contact metal 152 but also a doped semiconductor material 154, where the doped semiconductor material 154 may be at the bottom of the S/D contact 150 (i.e., in a portion of the S/D contact 150 that is surrounded by the channel material 118), while the contact metal 152 may be at the top of the S/D contact 150 (i.e., in a portion of the S/D contact 150 that is surrounded by the gate spacer 132, although a portion of the contact metal 152 may also be surrounded by the channel material 118, as illustrated in FIG. 8B). The doped semiconductor material 154 may include any suitable semiconductor material that has been doped to be electrically conductive. For example, the doped semiconductor material 154 may include any of the semiconductor materials described above with reference to the channel material 118, but with the dopant concentration of at least about 5×10¹⁸ dopants per cubic centimeter, e.g., at least about 5×10¹⁹ dopants per cubic centimeter or at least about 1×10²¹ dopants per cubic centimeter. In some embodiments, the doped semiconductor material 154 may have a bandgap that is lower than that of the channel material 118, e.g., lower than about 1.5 electron-Volt (eV). Implementing the doped semiconductor material 154 as a part of the S/D contact 150 that interfaces at least a portion of the channel material 118 may provide advantages in terms of reducing the height of a barrier to carrier transport compared to that of an interface between the contact metal 152 of the S/D contact 150 and the channel material 118.

FIG. 8C illustrates an embodiment where the S/D contact 150 may be provided in an opening in the channel material 118 and the gate spacer 132 with the doped semiconductor material 154 lining the sidewalls and the bottom of the opening and the contact metal 152 filling the rest of the space of the opening. Thus, in such an embodiment, only the doped semiconductor material 154 interfaces the channel material 118 and the contact metal 152 does not interface the channel material 118, which may further lower effective barrier height for the overall S/D contact 150, compared to the embodiment shown in FIG. 8B.

FIG. 8D illustrates an embodiment of the S/D contact 150 similar to that of FIG. 8C, but where the doped semiconductor material 154 lining the sidewalls and the bottom of the opening is recessed before the contact metal 152 is deposited to fill the rest of the space of the opening. Thus, in such an embodiment, the doped semiconductor material 154 interfaces some but not all of the channel material 118, and the contact metal 152 interfaces some of the channel material 118. Compared to the embodiment of FIG. 8B, the surface area of the doped semiconductor material 154 interfacing the channel material 118 in the embodiment of FIG. 8D may be substantially the same, but the surface area of the doped semiconductor material 154 interfacing the contact metal 152 may be increased, which may advantageously lead to smaller contact resistance. Compared to the embodiment of FIG. 8C, the embodiment of FIG. 8D may simplify manufacturing since it may be challenging to simultaneously polish the gate spacer 132, the contact metal 152, and the doped semiconductor material 154 at the same time if the embodiment of FIG. 8C is implemented. However, the embodiment of FIG. 8C may advantageously allow achieving lower effective barrier height for the overall S/D contact 150, compared to the embodiment shown in FIG. 8D, because of the increased interface between the channel material 118 and the doped semiconductor material 154 and decreased interface between the channel material 118 and the contact metal 152. Thus, one of the embodiments of FIG. 8C and 8D may prove to be more advantageous than the other depending on a particular deployment scenario.

FIGS. 9A-9D are cross-sectional side views of a S/D contact 160 that could be implemented at the bottom of a channel layer (e.g., the channel layer 116), in accordance with various embodiments. Thus, the S/D contact 160 is a back-side contact of the IC device 100 and may be either the second S/D contact 130 for any embodiments of FIGS. 1-6 or one of the first S/D contacts 128 for the embodiment of FIG. 7. Since the S/D contact 160 may be implemented in any embodiments of the IC device 100 as shown in FIGS. 1-7, or in any combination of these embodiments, FIGS. 9A-9D illustrate the channel material 118 and the intermediate layer 114 surrounding, respectively, top and bottom portions of the S/D contact 160, but further details of the IC device 100 are not shown in order to not clutter the drawings of FIGS. 9A-9D. In some embodiments of the IC device 100, what is illustrated as the intermediate layer 114 in FIGS. 9A-9D and in other drawings of the present disclosure may be any suitable insulator material or a support structure (e.g., the support structure 112).

FIG. 9A illustrates an embodiment where the S/D contact 160 may include only a contact metal 152 (similar to the embodiments of the S/D contact 150 shown in FIG. 8A).

FIG. 9B illustrates an embodiment where the S/D contact 160 may include not only a contact metal 152 but also a doped semiconductor material 154, where the doped semiconductor material 154 may be at the top of the S/D contact 160 (i.e., in a portion of the S/D contact 160 that is surrounded by the channel material 118), while the contact metal 152 may be at the bottom of the S/D contact 160 (i.e., in a portion of the S/D contact 160 that is surrounded by the intermediate layer 114, although a portion of the contact metal 152 may also be surrounded by the channel material 118, as illustrated in FIG. 9B). Embodiment of the S/D contact 160 shown in FIG. 9B is similar to the embodiments of the S/D contact 150 shown in FIG. 8B. Implementing the doped semiconductor material 154 as a part of the S/D contact 160 that interfaces at least a portion of the channel material 118 may provide advantages in terms of reducing the height of a barrier to carrier transport compared to that of an interface between the contact metal 152 of the S/D contact 160 and the channel material 118.

FIG. 9C illustrates an embodiment where the S/D contact 160 may be provided in an opening in the channel material 118 and the intermediate layer 114 with the doped semiconductor material 154 lining the sidewalls and the top of the opening and the contact metal 152 filling the rest of the space of the opening. Thus, in such an embodiment, only the doped semiconductor material 154 interfaces the channel material 118 and the contact metal 152 does not interface the channel material 118, which is similar to the embodiments of the S/D contact 150 shown in FIG. 8C. Implementing the S/D contact 160 in the manner as shown in FIG. 9C may provide advantages in terms of further lowering effective barrier height for the overall S/D contact 160, compared to the embodiment shown in FIG. 9B.

FIG. 9D illustrates an embodiment of the S/D contact 160 similar to that of FIG. 9C, but where the doped semiconductor material 154 lining the sidewalls and the bottom of the opening is recessed before the contact metal 152 is deposited to fill the rest of the space of the opening. Thus, in such an embodiment, the doped semiconductor material 154 interfaces some but not all of the channel material 118, and the contact metal 152 interfaces some of the channel material 118, which is similar to the embodiments of the S/D contact 150 shown in FIG. 8D. Compared to the embodiment of FIG. 9B, the surface area of the doped semiconductor material 154 interfacing the channel material 118 in the embodiment of FIG. 9D may be substantially the same, but the surface area of the doped semiconductor material 154 interfacing the contact metal 152 may be increased, which may advantageously lead to smaller contact resistance. Compared to the embodiment of FIG. 9C, the embodiment of FIG. 9D may simplify manufacturing since it may be challenging to simultaneously polish the gate spacer 132, the contact metal 152, and the doped semiconductor material 154 at the same time if the embodiment of FIG. 9C is implemented. However, the embodiment of FIG. 9C may advantageously allow achieving lower effective barrier height for the overall S/D contact 160, compared to the embodiment shown in FIG. 9D, because of the increased interface between the channel material 118 and the doped semiconductor material 154 and decreased interface between the channel material 118 and the contact metal 152. Thus, one of the embodiments of FIGS. 9C and 9D may prove to be more advantageous than the other depending on a particular deployment scenario.

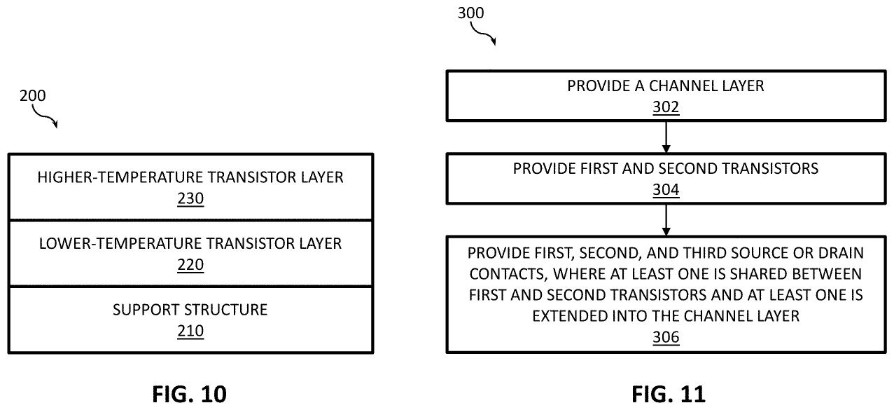

FIG. 10 is a high-level cross-sectional side view of an IC device assembly 200 with transistor layers configured for operation at different temperatures, in accordance with some embodiments. As shown in FIG. 10, the IC device assembly 200 may include a support structure 210, one or more lower-temperature transistor layers 220, and one or more higher-temperature transistor layers 230 so that the one or more lower-temperature transistor layers 220 are between the support structure 210 and the one or more higher-temperature transistor layers 230. The IC device assembly 200 may include any of the embodiments of the IC device 100 described with reference to FIGS. 1-9, or any combination of such embodiments, where the support structure 210 may be the support structure 112 of the IC device 100 and any of the lower-temperature transistor layers 220 and/or the higher-temperature transistor layers 230 may include transistors formed based on the channel material 118 with one or more S/D contacts extending into the channel material 118 as described above.

The lower-temperature transistor layers 220 may include transistors optimized for operating at relatively low temperatures, e.g., below about 200 Kelvin degrees, while the higher-temperature transistor layers 230 may include transistors optimized for operating at higher temperatures than the transistors of the lower-temperature transistor layers 220, e.g., at room temperature. Such optimization may be in terms of, e.g., choosing the channel material 118 (e.g., choosing a semiconductor material with a suitable bandgap), and deciding whether to implement S/D contacts extending into the channel material 118 according to any embodiments described above. The reasons why FIG. 10 illustrates that the lower-temperature transistor layers 220 may be closer to the support structure 210 than the higher-temperature transistor layers 230 may be as follows. At about room temperature, it may be advantageous to select the channel material 118 to be a relatively wider bandgap (e.g., greater than about 1.5 eV) semiconductor material, such as an oxide semiconductor material or any other thin-film semiconductor materials as described above, because semiconductor materials with lower bandgaps may result in too much leakage, compromising the performance of the transistors. On the other hand, at low temperature, oxide semiconductors lose their mobility, to non-oxide semiconductors may be preferable, such as those that may be epitaxially grown on a semiconductor support structure and, hence, the lower-temperature transistor layers 220 may be closer to the support structure 210 than the higher-temperature transistor layers 230. In some embodiments, 2D semiconductor materials such as graphene may be particularly advantageous for use in implementing lower-temperature vs higher-temperature transistors because it is relatively simple to modify their bandgap so that they may be used both for lower-temperature and higher-temperature operation. In some embodiments, the lower-temperature transistor layers 220 may implement transistors with shared S/D contacts and some of the S/D contacts extending into the channel material 118 according to any embodiments described above, while the higher-temperature transistor layers 230 may implement transistors where none of the S/D contacts extend into the channel material.

FIG. 11 is a flow diagram of an example method 300 of fabricating a shared contact IC device with S/D contacts extending into a channel layer (e.g., any embodiment or any combination of embodiments of the IC devices 100 described herein), in accordance with some embodiments. In various embodiments, the method 300 may include other operations not specifically shown in FIG. 11, such as various cleaning or planarization operations as known in the art. For example, in some embodiments, any of the layers of the IC device, or the individual IC structures provided within the IC device, may be cleaned prior to, after, or during any of the processes of the fabrication method described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the top surfaces of the IC devices, or the individual IC structures provided within the IC devices, described herein may be planarized prior to, after, or during any of the processes of the fabrication method described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

As shown in FIG. 11, the fabrication method 300 may include a process 302, that includes providing a channel layer. The channel layer provided in the process 302 may be the channel layer 116 as described herein and may be shaped to enable fabrication of transistors 110 of any suitable architecture. In various embodiments, a channel material of the channel layer provided in the process 302 may be provided according to any of the techniques described above with reference to the channel material 118, such as layer transfer, direct epitaxial growth, or thin-film deposition.

The method 300 may also include a process 304, that includes providing at least first and second transistors based on the channel layer provided in the process 302. The transistors provided in the process 304 may be the transistors 110-1, 110-2 as described herein. In some embodiments, the process 304 may include providing gate stacks of the first and second transistors. In such embodiments, the gate stacks provided in the process 304 may be the gate stacks 120-1, 120-2 as described herein.

The method 300 may further include a process 306, that includes providing at least first, second, and third S/D contacts for the first and second transistors provided in the process 304, where at least one of the S/D contacts is shared between the first and second transistors and at least one of the S/D contacts is extended into the channel layer. The first, second, and third S/D contacts provided in the process 306 may be the first S/D contacts 128 and the second S/D contact 130 as described herein.

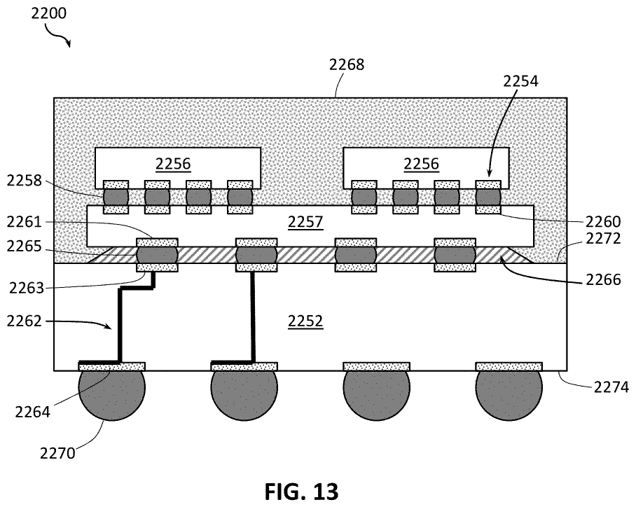

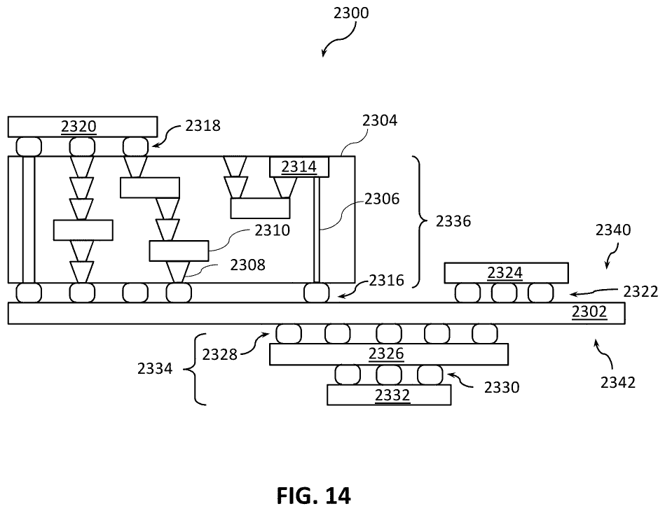

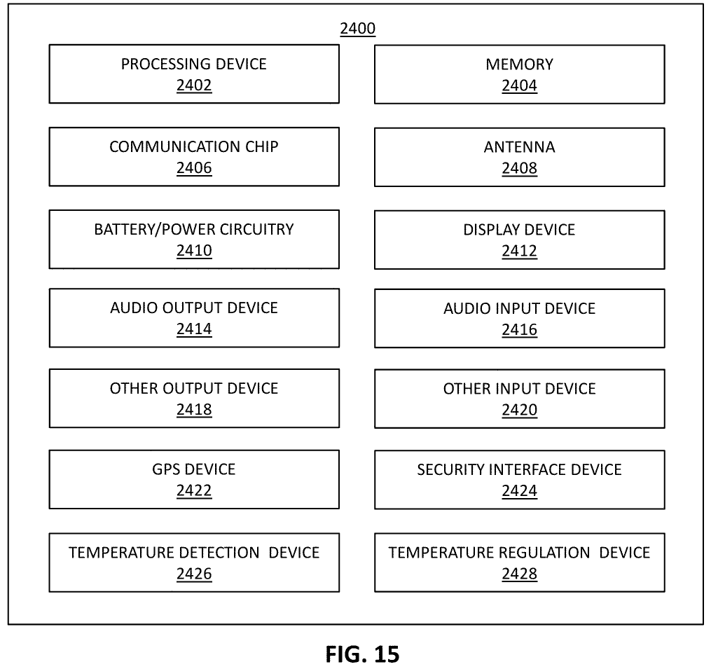

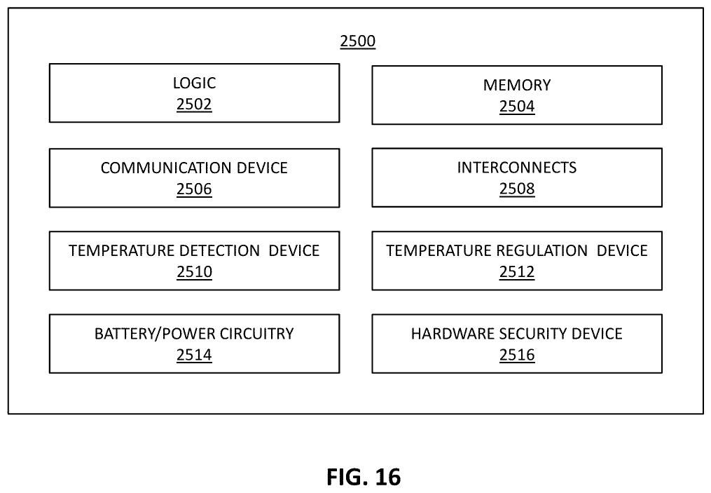

The method 300 may further include processes for fabricating larger device assemblies, e.g., for fabricating an IC package 2200 of FIG. 13, for fabricating an IC device assembly 2300 of FIG. 14, for fabricating a computing device 2400 of FIG. 15, or for fabricating a processing device 2500 of FIG. 16.

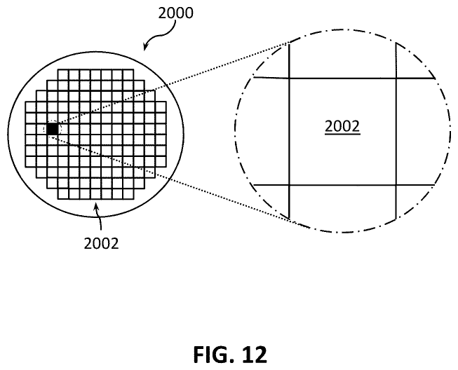

The shared contact IC devices with S/D contacts extending into a channel layer disclosed herein may be included in any suitable electronic device. FIGS. 12-16 illustrate various examples of devices, packages, and assemblies that may include one or more of the shared contact IC devices with S/D contacts extending into a channel layer disclosed herein.

FIG. 12 illustrates top views of a wafer 2000 and dies 2002 that may include one or more IC devices shared contact IC devices with S/D contacts extending into a channel layer in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 13. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more shared contact IC devices with S/D contacts extending into a channel layer as described herein). After the fabrication of the semiconductor product is complete (e.g., after manufacture of any embodiment of the IC device 100 as described herein), the wafer 2000 may undergo a singulation process in which each of the dies 2002 is separated from one another to provide discrete “chips” of the semiconductor product. In particular, devices that include one or more shared contact IC devices with S/D contacts extending into a channel layer as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a hysteretic memory device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 10) or other logic that is configured to store information in the memory devices or execute instructions stored in the memory array.

FIG. 13 is a side, cross-sectional view of an example IC package 2200 that may include one or more shared contact IC devices with S/D contacts extending into a channel layer in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 13 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 13 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 13 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 14.

The dies 2256 may take the form of any of the embodiments of the die 2002 discussed herein (e.g., may include any of the embodiments of the shared contact IC devices with S/D contacts extending into a channel layer as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more shared contact IC devices with S/D contacts extending into a channel layer, e.g., as discussed above; in some embodiments, at least some of the dies 2256 may not include shared contact IC devices with S/D contacts extending into a channel layer.

The IC package 2200 illustrated in FIG. 13 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 13, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 14 is a cross-sectional side view of an IC device assembly 2300 that may include components having one or more shared contact IC devices with S/D contacts extending into a channel layer in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more shared contact IC devices with S/D contacts extending into a channel layer in accordance with any of the embodiments disclosed herein; e.g., any of the IC packages discussed below with reference to the IC device assembly 2300 may take the form of any of the embodiments of the IC package 2200 discussed above with reference to FIG. 13 (e.g., may include one or more shared contact IC devices with S/D contacts extending into a channel layer provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 14 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 14), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 12), an IC device, or any other suitable component. In particular, the IC package 2320 may include one or more shared contact IC devices with S/D contacts extending into a channel layer as described herein. Although a single IC package 2320 is shown in FIG. 14, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 14, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 14 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 15 is a block diagram of an example computing device 2400 that may include one or more components including one or more shared contact IC devices with S/D contacts extending into a channel layer in accordance with any of the embodiments disclosed herein. For example, any suitable ones of the components of the computing device 2400 may include a die (e.g., the die 2002 of FIG. 12) having one or more transistors 110 with S/D contacts extending into a channel layer as described herein. Any one or more of the components of the computing device 2400 may include, or be included in, an IC package 2200 of FIG. 13 or an IC device 2300 of FIG. 14.

A number of components are illustrated in FIG. 15 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 15, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 16 is a block diagram of an example processing device 2500 that may include one or more shared contact IC devices with S/D contacts extending into a channel layer in accordance with any of the embodiments disclosed herein. For example, any suitable ones of the components of the processing device 2500 may include a die (e.g., the die 2002 of FIG. 12) having one or more transistors 110 with S/D contacts extending into a channel layer as described herein. Any one or more of the components of the processing device 2500 may include, or be included in, an IC device 1400 (FIG. 14). Any one or more of the components of the processing device 2500 may include, or be included in, an IC package 2200 of FIG. 13 or an IC device 2300 of FIG. 14. Any one or more of the components of the processing device 2500 may include, or be included in, a computing device 2400 of FIG. 15; for example, the processing device 2500 may be the processing device 2402 of the computing device 2400.

A number of components are illustrated in FIG. 16 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 16, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 15). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 15). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 15 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 15 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 15. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 15. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

The following paragraphs provide various examples of the embodiments disclosed herein.

Example 1 provides an IC device that includes a support structure (e.g., a substrate, a die, a wafer, or a chip, e.g., a support structure 112); a channel layer provided over the support structure (e.g., a channel layer 116, including a channel material 118); a first transistor and a second transistor (e.g., transistors 110-1 and 110-2); and a plurality of contacts including at least a first contact, a second contact, and a third contact, where a channel region of the first transistor (e.g., a channel region 111-1) includes a first portion of the channel layer, a channel region of the second transistor (e.g., a channel region 111-2) includes a second portion of the channel layer, the first contact (e.g., a first S/D contact 128 of the transistor 110-1) is a first one of a pair of a source contact and a drain contact of the first transistor, the third contact (e.g., a first S/D contact 128 of the transistor 110-2) is a first one of a pair of a source contact and a drain contact of the second transistor, the second contact (e.g., a second S/D contact 130, shared between the transistors 110-1 and 110-2) is a second one of the pair of the source contact and the drain contact of the first transistor and a second one of the pair of the source contact and the drain contact of the second transistor, and at least one of the first contact, the second contact, and the third contact extends into the channel layer.

Example 2 provides the IC device according to example 1, where the channel layer has a first face and an opposing second face, the second contact has a portion at the first face of the channel layer, the first contact has a portion at the second face of the channel layer and is one of the at least one of the first contact, the second contact, and the third contact that extends into the channel layer (e.g., the first contact extends into the channel layer from the second face of the channel layer), the first transistor has a gate having a portion at the second face of the channel layer and extending into the channel layer from the second face of the channel layer, and a portion of the channel layer is between a portion of the first contact that extends into the channel layer and a portion of the gate that extends into the channel layer (i.e., the portion of the first contact that extends into the channel layer is not in contact with the portion of the gate that extends into the channel layer).

Example 3 provides the IC device according to example 2, where a distance between the portion of the first contact that extends into the channel layer and the portion of the gate that extends into the channel layer is between about 1 and 20 nanometers, including all values and ranges therein, e.g., between about 1 and 10 nanometers, or between about 1 and 5 nanometers.

Example 4 provides the IC device according to any one of examples 2-3, where the gate of the first transistor is a first gate, the third contact has a portion at the second face of the channel layer and is another one of the at least one of the first contact, the second contact, and the third contact that extends into the channel layer (e.g., the third contact extends into the channel layer from the second face of the channel layer), the second transistor has a second gate having a portion at the second face of the channel layer and extending into the channel layer from the second face of the channel layer, and a further portion of the channel layer is between a portion of the third contact that extends into the channel layer and a portion of the second gate that extends into the channel layer (i.e., the portion of the third contact that extends into the channel layer is not in contact with the portion of the second gate that extends into the channel layer).

Example 5 provides the IC device according to example 4, where a distance between the portion of the third contact that extends into the channel layer and the portion of the second gate that extends into the channel layer is between about 1 and 20 nanometers, including all values and ranges therein, e.g., between about 1 and 10 nanometers, or between about 1 and 5 nanometers.

Example 6 provides the IC device according to any one of examples 2-5, where the second contact extends into the channel layer from the first face of the channel layer, and a portion of the channel layer is between a portion of the second contact that extends into the channel layer and the portion of the gate that extends into the channel layer (i.e., the portion of the third contact that extends into the channel layer is not in contact with the portion of the gate that extends into the channel layer).

Example 7 provides the IC device according to example 6, where a distance between the portion of the second contact that extends into the channel layer and the portion of the second gate that extends into the channel layer is between about 1 and 20 nanometers, including all values and ranges therein, e.g., between about 1 and 10 nanometers, or between about 1 and 5 nanometers.

Example 8 provides the IC device according to any one of examples 2-7, where the gate further has a portion in an insulating material at the second face of the channel layer.

Example 9 provides the IC device according to any one of examples 2-7, where the gate does not have a portion in an insulating material at the second face of the channel layer.

Example 10 provides the IC device according to any one of examples 2-9, where the first face of the channel layer is closer to the support structure than the second face of the channel layer.

Example 11 provides the IC device according to any one of examples 2-9, where the second face of the channel layer is closer to the support structure than the first face of the channel layer.

Example 12 provides the IC device according to example 1, where the channel layer has a first face and an opposing second face, and the at least one of the first contact, the second contact, and the third contact that extends into the channel layer extends from the second face of the channel layer to the first face of the channel layer.

Example 13 provides the IC device according to example 12, where the at least one of the first contact, the second contact, and the third contact that extends into the channel layer from the second face of the channel layer to the first face of the channel layer extends further into an insulating material at the first face of the channel layer.

Example 14 provides the IC device according to example 1, where the channel layer has a first face and an opposing second face, and the at least one of the first contact, the second contact, and the third contact that extends into the channel layer extends from the second face of the channel layer towards the first face of the channel layer but does not reach the first face of the channel layer.

Example 15 provides the IC device according to any one of examples 12-14, where the first face of the channel layer is closer to the support structure than the second face of the channel layer.

Example 16 provides the IC device according to any one of examples 12-14, where the second face of the channel layer is closer to the support structure than the first face of the channel layer.

Example 17 provides the IC device according to example 1, where the channel layer has a first face and an opposing second face, the second contact has a portion at the first face of the channel layer, the first contact has a portion at the second face of the channel layer and is one of the at least one of the first contact, the second contact, and the third contact that extends into the channel layer (e.g., the first contact extends into the channel layer from the second face of the channel layer), the first transistor has a gate having a portion at the second face of the channel layer and extending into the channel layer from the second face of the channel layer, and a portion of the first contact that extends into the channel layer is in contact with a portion of the gate that extends into the channel layer.

Example 18 provides the IC device according to example 17, where the first face of the channel layer is closer to the support structure than the second face of the channel layer.

Example 19 provides the IC device according to example 17, where the second face of the channel layer is closer to the support structure than the first face of the channel layer.

Example 20 provides the IC device according to any one of examples 1-19, where the at least one of the first contact, the second contact, and the third contact that extends into the channel layer includes a metal.

Example 21 provides the IC device according to example 20, where the at least one of the first contact, the second contact, and the third contact that extends into the channel layer further includes a semiconductor material in contact with the metal, the semiconductor material having a bandgap that is smaller than at least one of a bandgap of a semiconductor material of the channel region of the first transistor, and a bandgap of a semiconductor material of the channel region of the second transistor.

Example 22 provides the IC device according to example 21, where at least a portion of the semiconductor material of the at least one of the first contact, the second contact, and the third contact that extends into the channel layer is in contact with the channel layer, and no portion of the metal of the at least one of the first contact, the second contact, and the third contact that extends into the channel layer is in contact with the channel layer.

Example 23 provides the IC device according to example 21, where at least a portion of the semiconductor material of the at least one of the first contact, the second contact, and the third contact that extends into the channel layer is in contact with the channel layer, and at least a portion of the metal of the at least one of the first contact, the second contact, and the third contact that extends into the channel layer is in contact with the channel layer.

Example 24 provides the IC device according to any one of examples 21-23, where the semiconductor material of the at least one of the first contact, the second contact, and the third contact that extends into the channel layer has dopants at a concentration of at least about 5×10¹⁸ dopants per cubic centimeter, e.g., at least about 5×10¹⁹ dopants per cubic centimeter or at least about 1×10²¹ dopants per cubic centimeter.

Example 25 provides the IC device according to example 24, where the at least one of the first contact, the second contact, and the third contact that extends into the channel layer extends into a portion of the channel layer that includes a semiconductor material having dopants at a concentration of at least about 5×10¹⁸ dopants per cubic centimeter, e.g., at least about 5×10¹⁹ dopants per cubic centimeter or at least about 1×10²¹ dopants per cubic centimeter.

Example 26 provides the IC device according to any one of examples 1-25, where at least one of the channel region of the first transistor and the channel region of the second transistor includes a semiconductor material having an average grain size larger than about 1 millimeter.

Example 27 provides the IC device according to any one of examples 1-25, where at least one of the channel region of the first transistor and the channel region of the second transistor includes a semiconductor material having an average grain size smaller than about 1 millimeter.

Example 28 provides the IC device according to any one of examples 1-27, where the channel layer is a fin or a nanoribbon.

Example 29 provides the IC device according to any one of examples 1-28, further including a first storage element coupled to the first contact; a second storage element coupled to the third contact; and a bitline coupled to the second contact. In various embodiments, any of the first and second storage elements may be one of a capacitor, a magnetoresistive element, ferroelectric element, or a resistance-changing element.

Example 30 provides an IC package that includes an IC die, including an IC device according to any one of the preceding examples (e.g., any one of examples 1-29); and a further component, coupled to the IC die.

Example 31 provides the IC package according to example 30, where the further component is one of a package substrate, an interposer, or a further IC die.

Example 32 provides the IC package according to examples 30 or 31, where the further component is coupled to the IC die via one or more first-level interconnects, where the one or more first-level interconnects include one or more solder bumps, solder posts, or bond wires.

Example 33 provides the IC package according to any one of examples 30-32, where the IC die includes, or is a part of, at least one of a memory device, a computing device, a wearable device, a handheld electronic device, and a wireless communications device.

Example 34 provides an electronic device that includes a carrier substrate; and one or more of the IC devices according to any one of the preceding examples and/or the IC package according to any one of the preceding examples, coupled to the carrier substrate.

Example 35 provides the electronic device according to example 34, where the carrier substrate is a motherboard.

Example 36 provides the electronic device according to example 34, where the carrier substrate is a PCB.

Example 37 provides the electronic device according to any one of examples 34-36, where the electronic device is a wearable electronic device (e.g., a smart watch) or handheld electronic device (e.g., a mobile phone).

Example 38 provides the electronic device according to any one of examples 34-37, where the electronic device further includes one or more communication chips and an antenna.

Example 39 provides the electronic device according to any one of examples 34-38, where the electronic device is memory device.

Example 40 provides the electronic device according to any one of examples 34-38, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 41 provides the electronic device according to any one of examples 34-38, where the electronic device is a computing device.

Example 42 provides the electronic device according to any one of examples 34-41, where the electronic device is included in a base station of a wireless communication system.

Example 43 provides the electronic device according to any one of examples 34-41, where the electronic device is included in a user equipment device (i.e., a mobile device) of a wireless communication system.

Example 44 provides a method of fabricating an IC device, the method including: providing a channel layer (e.g., a channel layer 116, including a channel material 118) over a support structure (e.g., a substrate, a die, a wafer, or a chip, e.g., a support structure 112); providing a first transistor and a second transistor (e.g., transistors 110-1 and 110-2); and providing a plurality of contacts including at least a first contact, a second contact, and a third contact, where a channel region of the first transistor (e.g., a channel region 111-1) includes a first portion of the channel layer, a channel region of the second transistor (e.g., a channel region 111-2) includes a second portion of the channel layer, the first contact (e.g., a first S/D contact 128 of the transistor 110-1) is a first one of a pair of a source contact and a drain contact of the first transistor, the third contact (e.g., a first S/D contact 128 of the transistor 110-2) is a first one of a pair of a source contact and a drain contact of the second transistor, the second contact (e.g., a second S/D contact 130, shared between the transistors 110-1 and 110-2) is a second one of the pair of the source contact and the drain contact of the first transistor and a second one of the pair of the source contact and the drain contact of the second transistor, and at least one of the first contact, the second contact, and the third contact extends into the channel layer.

Example 45 provides the method according to example 44, where providing the first transistor includes providing a gate stack of the first transistor, where the gate stack is at least partially recessed into the channel layer.

Example 46 provides the method according to examples 44 or 45, further including processes for fabricating the IC device according to any one of the preceding examples (e.g., any one of examples 1-29).

Example 47 provides the method according to any one of examples 44-46, further including processes for fabricating an IC package according to any one of the preceding examples (e.g., any one of examples 30-33).

Example 48 provides the method according to any one of examples 44-47, further including processes for fabricating an electronic device according to any one of the preceding examples (e.g., any one of examples 34-43).

1. An integrated circuit (IC) device, comprising:
a support structure;
a channel layer over the support structure;
a first transistor and a second transistor; and
a first contact, a second contact, and a third contact,
wherein:
a channel region of the first transistor includes a first portion of the channel layer,
a channel region of the second transistor includes a second portion of the channel layer,
the first contact is a first one of a pair of a source contact and a drain contact of the first transistor,
the third contact is a first one of a pair of a source contact and a drain contact of the second transistor,
the second contact is a second one of the pair of the source contact and the drain contact of the first transistor and a second one of the pair of the source contact and the drain contact of the second transistor, and
at least one of the first contact, the second contact, and the third contact extends into the channel layer.

2. The IC device according to claim 1, wherein:
the channel layer has a first face and an opposing second face,
the second contact has a portion at the first face of the channel layer,
the first contact has a portion at the second face of the channel layer and is one of the at least one of the first contact, the second contact, and the third contact that extends into the channel layer,
the first transistor has a gate having a portion at the second face of the channel layer and extending into the channel layer, and
a portion of the channel layer is between a portion of the first contact that extends into the channel layer and a portion of the gate that extends into the channel layer.

3. The IC device according to claim 2, wherein a distance between the portion of the first contact that extends into the channel layer and the portion of the gate that extends into the channel layer is between about 1 and 20 nanometers.

4. The IC device according to claim 2, wherein:
the second contact extends into the channel layer from the first face of the channel layer, and
a portion of the channel layer is between a portion of the second contact that extends into the channel layer and the portion of the gate that extends into the channel layer.

5. The IC device according to claim 4, wherein a distance between the portion of the second contact that extends into the channel layer and the portion of the second gate that extends into the channel layer is between about 1 and 20 nanometers.

6. The IC device according to claim 2, wherein:
the first face of the channel layer is closer to the support structure than the second face of the channel layer.

7. The IC device according to claim 2, wherein:
the second face of the channel layer is closer to the support structure than the first face of the channel layer.

8. The IC device according to claim 1, wherein:
the channel layer has a first face and an opposing second face, and
the at least one of the first contact, the second contact, and the third contact that extends into the channel layer extends from the second face of the channel layer to the first face of the channel layer.

9. The IC device according to claim 8, wherein:
the at least one of the first contact, the second contact, and the third contact that extends into the channel layer from the second face of the channel layer to the first face of the channel layer extends further into an insulating material at the first face of the channel layer.

10. The IC device according to claim 1, wherein:
the channel layer has a first face and an opposing second face, and
the at least one of the first contact, the second contact, and the third contact that extends into the channel layer extends from the second face of the channel layer towards the first face of the channel layer but does not reach the first face of the channel layer.

11. The IC device according to claim 1, wherein:
the channel layer has a first face and an opposing second face,
the second contact has a portion at the first face of the channel layer,
the first contact has a portion at the second face of the channel layer and is one of the at least one of the first contact, the second contact, and the third contact that extends into the channel layer,
the first transistor has a gate having a portion at the second face of the channel layer and extending into the channel layer, and
a portion of the first contact that extends into the channel layer is in contact with a portion of the gate that extends into the channel layer.

12. The IC device according to claim 1, wherein:
the at least one of the first contact, the second contact, and the third contact that extends into the channel layer includes a metal and a semiconductor material in contact with the metal, and
the semiconductor material has a bandgap that is smaller than at least one of:
a bandgap of a semiconductor material of the channel region of the first transistor, and
a bandgap of a semiconductor material of the channel region of the second transistor.

13. The IC device according to claim 12, wherein:
at least a portion of the semiconductor material of the at least one of the first contact, the second contact, and the third contact that extends into the channel layer is in contact with the channel layer, and
no portion of the metal of the at least one of the first contact, the second contact, and the third contact that extends into the channel layer is in contact with the channel layer.

14. The IC device according to claim 12, wherein:
at least a portion of the semiconductor material of the at least one of the first contact, the second contact, and the third contact that extends into the channel layer is in contact with the channel layer, and
at least a portion of the metal of the at least one of the first contact, the second contact, and the third contact that extends into the channel layer is in contact with the channel layer.

15. The IC device according to claim 12, wherein:
the semiconductor material of the at least one of the first contact, the second contact, and the third contact that extends into the channel layer has dopants at a concentration of at least about 5×10²⁰ dopants per cubic centimeter.

16. The IC device according to claim 1, wherein at least one of the channel region of the first transistor and the channel region of the second transistor includes a semiconductor material having an average grain size larger than about 1 millimeter.

17. The IC device according to claim 1, wherein at least one of the channel region of the first transistor and the channel region of the second transistor includes a semiconductor material having an average grain size smaller than about 1 millimeter.

18. The IC device according to claim 1, wherein the channel layer is a fin, a nanoribbon, or a nanowire.

19. A method of fabricating an integrated circuit (IC) device, the method comprising:
providing a channel layer over a support structure;
providing a first transistor and a second transistor; and
providing a first contact, a second contact, and a third contact,
wherein:
a channel region of the first transistor includes a first portion of the channel layer,
a channel region of the second transistor includes a second portion of the channel layer,
the first contact is a first one of a pair of a source contact and a drain contact of the first transistor,
the third contact a first one of a pair of a source contact and a drain contact of the second transistor,
the second contact is a second one of the pair of the source contact and the drain contact of the first transistor and a second one of the pair of the source contact and the drain contact of the second transistor, and
at least one of the first contact, the second contact, and the third contact extends into the channel layer.

20. The method according to claim 19, wherein providing the first transistor includes providing a gate stack of the first transistor, wherein the gate stack is at least partially recessed into the channel layer.
